(19) United States
(12) Patent Application Publication
(10) Pub. No.: US 2026/0211180 A1
(43) Pub. Date: Jul. 23, 2026

(54) HETEROGENEOUS INTEGRATED COHERENT RECEIVER BASED ON WAFER-SCALE INDIUM PHOSPHIDE-LITHIUM NIOBATE INTEGRATED PLATFORM

(71) Applicant: Southwest Jiaotong University, Chengdu (CN)

(72) Inventors: Xiaojun Xie, Chengdu (CN); Chao Wei, Chengdu (CN); Xihua Zou, Chengdu (CN); Wei Pan, Chengdu (CN); Lianshan Yan, Chengdu (CN)

(21) Appl. No.: 19/408,511

(22) Filed: Dec. 4, 2025

(30) Foreign Application Priority Data
Jan. 20, 2025 (CN) 202510084225.8

(51) Int. Cl. G02B 6/122; G02B 6/12; G02B 6/136; H10F 39/10

(52) U.S. Cl. CPC G02B 6/122; G02B 6/136; H10F 39/103; G02B 2006/1204; G02B 2006/12147

(57) ABSTRACT

A heterogeneous integrated coherent receiver based on a wafer-scale indium phosphide (InP)-lithium niobate integrated platform is provided and includes an on-chip 2×4 90° optical hybrid coupler and a pair of heterogeneous integrated balanced photodetectors (BPDs). The on-chip 2×4 90° optical hybrid coupler includes a 2×4 multimode interference (MMI) coupler based on symmetrical interference and a 2×2 MMI coupler based on general interference. Each BPD demonstrates a 3 dB bandwidth of 60 GHz and a common mode rejection ratio greater than 20 dB. The heterogeneous integrated coherent receiver has a wide balanced detection bandwidth of 60 GHz and low power consumption of 9.6 fJ/bit, supports data reception of 600 Gbit/s/Pol per channel. This heterogeneous integrated coherent receiver has the characteristics of a record high bandwidth, ultra-low power consumption and ultra-large capacity, which surpasses all other integrated optical coherent receivers shown so far.

### CROSS-REFERENCE TO RELATED APPLICATION

This application claims priority to Chinese patent application No. CN 202510084225.8, filed to China National Intellectual Property Administration (CNIPA) on Jan. 20, 2025, which is herein incorporated by reference in its entirety.

### TECHNICAL FIELD

The present disclosure relates to the field of optical communication technologies, and particularly to a heterogeneous integrated coherent receiver based on a wafer-scale indium phosphide (InP)-lithium niobate integrated platform.

### BACKGROUND

The increasing demand for higher data rates in optical communication systems has promoted the exploration and development of advanced technologies that can support terabit transmission per second, referring to C. Xie and B. Zhang, “Scaling Optical Interconnects for Hyperscale Data Center Networks”, Proceedings of the IEEE, vol. 110, no. 11, pp. 1699-1713 November 2022, Doi: 10.1109/JPROC.2022.3178977. The demand for high-performance and compact devices is more urgent than ever. Photon transmitters and photon receivers are components of advanced optical communication systems, and must be continuously developed to meet these urgent demands.

Thin-film lithium niobate (LiNbO₃) has become a promising platform in high-performance photonic integrated circuits, because it has superior electro-optical characteristics, a wide transparent window, tight mode constraints and compatibility with mass manufacturing processes, referring to Z. Li et al., “High density lithium niobate photonic integrated circuits,” Nat. Commun., vol. 14, no. 1, p. 4856, 2023. A most advanced thin-film lithium niobate I/Q modulator has demonstrated excellent performance with a bandwidth exceeding 110 GHz and a half-wave voltage (V_{π}) less than 1 V, referring to M. Xu et al., “Dual-polarization thin-film lithium niobate in-phase quadrature modulators for terabit-per-second transmission,” Optica, OPTICA, vol. 9, no. 1, pp. 61-62, January 2022, Doi: 10.1364/OPTICA.449691. Further, a variety of high-performance lasers (referring to C. O. de Beeck et al., “III/V-on-lithium niobate amplifiers and lasers”, Optica, vol. 8, no. 10, pp. 1288-1289 October 2021, Doi: 10.1364/optica.438620) and high-speed photodetectors (referring to C. Wei et al., “Ultra-wideband Waveguide-coupled Photodiodes Heterogeneously Integrated on a Thin-film Lithium Niobate Platform,” Light: Advanced Manufacturing, vol. 4, no. 3, pp. 263-271, December 2023, Doi: 10.37188/lam.2023.030) have been realized on the thin-film lithium niobate platform through hybrid and heterogeneous integration technologies. However, despite these advances, the goal of realizing ultra-high-speed coherent receiver chips, which are key devices for ultra-high-capacity optical communication, ultra-high-speed photonic computing, and high-performance microwave photonics, has not yet been achieved on the thin-film lithium niobate platform. This is mainly due to lack of a reliable wafer-scale heterogeneous integration platform, which greatly limits the application of thin film integrated chips in photonic systems.

### SUMMARY

In view of the above problems, the present disclosure provides a heterogeneous integrated coherent receiver based on a wafer-scale indium phosphide (InP)-lithium niobate integrated platform.

In an embodiment, the present disclosure provides a heterogeneous integrated coherent receiver based on a wafer-scale indium phosphide (InP)-lithium niobate integrated platform, and the heterogeneous integrated coherent receiver includes an on-chip 2×4 90° optical hybrid coupler and a pair of heterogeneous integrated balanced photodetectors. The on-chip 2×4 90° optical hybrid coupler includes a 2×4 multimode interference (MMI) coupler based on symmetrical interference and a 2×2 MMI coupler based on general interference. The 2×4 MMI coupler based on symmetrical interference has a wedge-shaped structure. The 2×2 MMI coupler based on general interference is configured to adjust a phase relationship of one pair of two output pairs of the 2×4 MMI coupler based on symmetrical interference as 90°.

In an embodiment, an epitaxial layer structure of the photodetector is grown on a 2-inch semi-insulating InP substrate using metal-organic chemical vapor deposition (MOCVD). A heavily p-doped InGaAs layer is first deposited as a p-contact layer, followed by an InP buffer layer. Gradient p-doped In_{0.53}Ga_{0.47}As absorption layers are utilized to generate a self-induced electric field, accelerating the diffusion of photogenerated electrons. To alleviate the space-charge effect arising from the InGaAs/InP band discontinuity, an n-doped InGaAs depletion layer, an InGaAsP transition layer, and an InP cliff layer are introduced. The InGaAsP layer serves to reduce conduction band offset, while the combination of the n-doped InGaAs depletion layer and the InP cliff layer enhance the local electric field to support efficient electron transport. A p-doped sacrificial layer is employed to adjust the electric field in the drift region so that the field satisfies the condition for electron velocity overshoot. A heavily n-doped InP layer is used as both an n-contact layer and a matching layer. A thickness of the matching layer is optimized as 300 nm to achieve a uniform absorption profile, enhancing an output RF power. After bonding, the epitaxial layer structure adopts an n-down configuration, contributing to reduced contact resistance.

In an embodiment, before bonding of an indium phosphide wafer and a thin-film lithium niobate wafer, lithium niobate waveguides and passive devices are fabricated on the thin-film lithium niobate wafer by using an argon-based dry etching process; and after the bonding of the indium phosphide wafer and the thin-film lithium niobate wafer, the following steps are sequentially performed: an InP substrate is selectively etched by using a hydrochloric acid-based solution, p and n mesas are fabricated through a chlorine gas dry etching process to form a main structure of the balanced photodetectors, a layer of SiO₂ is deposited over an entire wafer surface as a passivation layer, and metal electrodes are formed by electroplating and lift-off processes after creating openings.

In an embodiment, the heterogeneous integrated coherent receiver has a wide balanced detection bandwidth of 60 GHz and low power consumption of 9.6 femtojoules (fJ)/bit, and supports data reception of 600 Gbit/s/Pol per channel.

The present disclosure has at least the following beneficial technical effects.

The heterogeneous integrated coherent receiver of the present disclosure has a wide balanced detection bandwidth of 60 GHz and low power consumption of 9.6 fJ/bit, supports data reception of 600 Gbit/s/Pol per channel, and supports data reception of 7 channels with a total of 3.584 Tbit/s/Pol. This heterogeneous integrated coherent receiver has the characteristics of a record high bandwidth, ultra-low power consumption and ultra-large capacity, which surpasses all other integrated optical coherent receivers shown so far. It provides a potential way for the interconnection of future P bit/s very large-scale data centers.

### BRIEF DESCRIPTION OF DRAWINGS

FIG. 1 illustrates the fabrication process of the heterogeneous integrated coherent receiver based on a wafer-scale InP-lithium niobate integrated platform according to an embodiment of the present disclosure.

FIG. 2 illustrates the bonded wafer.

FIG. 3 illustrates a colored microscope image of the lithium niobate waveguide.

FIG. 4 illustrates a schematic diagram of the heterogeneous integrated coherent receiver of the present disclosure.

FIG. 5 illustrates a comparison between the heterogeneous integrated coherent receiver of the present disclosure and a coin.

FIG. 6 illustrates a schematic diagram of a 2×4 90° optical hybrid coupler.

FIG. 7 illustrates simulated optical power variation of the 2×4 90° optical hybrid coupler.

FIG. 8 illustrates a transmission spectrum of an output of the 2×4 90° optical hybrid coupler in a c-band measured by a Mach-Zehnder delay interferometer, in which, an illustration shows a measured phase deviation of the 2×4 90° optical hybrid coupler.

FIG. 9 illustrates frequency responses of a balanced photodetector (BPD) in a differential mode and a common mode.

FIG. 10 illustrates the experimental setup for coherent detection.

FIG. 11 illustrates constellation diagrams and bit error rates (BERs) of a 100 Gigabaud (Gbaud) quadrature phase shift keying (QPSK) signal, a 128 Gbaud QPSK signal, an 80 Gbaud 16 quadrature amplitude modulation (QAM) signal, a 100 Gbaud 16 QAM signal, a 128 Gbaud 16 QAM signal, an 80 Gbaud 32 QAM signal, a 100 Gbaud 32 QAM signal, an 80 Gbaud 64 QAM signal, and a 100 Gbaud 64 QAM signal in back-to-back transmission.

FIG. 12 illustrates a relationship between the BER and the received optical power under a 100 Gbaud QPSK signal, a 100 Gbaud 16 QAM signal and a 100 Gbaud 32 QAM signal.

FIG. 13 illustrates constellation diagrams and BERs for a 100 Gbaud 16 QAM signal and a 100 Gbaud QPSK signal transmitted over distances of 25 km and 1040 km, respectively.

FIG. 14 illustrates experimental results of multichannel coherent reception.

### DETAILED DESCRIPTION OF EMBODIMENTS

The present disclosure will be described in further detail with reference to accompanying drawings and specific embodiments.

In an embodiment, the present disclosure provides a heterogeneous integrated coherent receiver based on a wafer-scale indium phosphide (InP)-lithium niobate integrated platform, the heterogeneous integrated coherent receiver includes an on-chip 2×4 90° optical hybrid coupler and a pair of heterogeneous integrated balanced photodetectors.

An epitaxial layer structure of the photodetector is shown in Table 1, which is grown by MOCVD on a 2-inch semi-insulating InP substrate. A 50-nm heavily p-doped InGaAs layer (2×10¹⁹ cm⁻³) was first deposited as a p-contact layer, followed by a 100-nm InP buffer layer. Gradient p-doped In_{0.53}Ga_{0.47}As absorption layers (with doping levels decreasing from 2×10¹⁸ cm⁻³ to 5×10¹⁷ cm⁻³) are utilized to generate a self-induced electric field, accelerating the diffusion of photogenerated electrons. To alleviate the space-charge effect arising from the InGaAs/InP band discontinuity, an n-doped InGaAs depletion layer, an InGaAsP transition layer, and an InP cliff layer are introduced. The InGaAsP layers serves to reduce conduction band offset, while the combination of the n-doped InGaAs depletion layer and the InP cliff layer enhance the local electric field to support efficient electron transport. A 40-nm p-doped sacrificial layer (1×10¹⁸ cm⁻³) is employed to adjust the electric field in the drift region so that the field satisfies the condition for electron velocity overshoot. A heavily n-doped InP layer (8×10¹⁸ cm⁻³) is used as an n-contact layer and the matching layer. A thickness of the matching layer is optimized as 300 nm to achieve a uniform absorption profile, enhancing an output RF power. After bonding, the epitaxial layer structure adopts an n-down configuration, contributing to reduced contact resistance.

TABLE 1
Epi structure of the photodiode

| | | | | Concentration | |
|---|---|---|---|---|---|
| Layer | Material | Thickness | | (cm⁻³) | Type |
| N-contact layer | InP | 300 | nm | 8 × 10¹⁸ | N |
| Matching layer | | | | | |
| Cladding layer | InP | 100 | nm | 5 × 10¹⁸ | N |
| Sacrificial layer | InP | 40 | nm | 1 × 10¹⁸ | P |
| Drift layer | InP | 120 | nm | 3 × 10¹⁶ | N |
| Cliff layer | InP | 20 | nm | 3 × 10¹⁷ | N |
| Smooth layer | InGaAsP, Q1.1 | 10 | nm | 1 × 10¹⁶ | N |
| | InGaAsP, Q1.4 | 10 | nm | 1 × 10¹⁶ | N |
| Depleted absorption | In_{0.53}Ga_{0.47}As | 30 | nm | 1 × 10¹⁶ | N |
| layer | In_{0.53}Ga_{0.47}As | 30 | nm | 5 × 10¹⁷ | P |
| Graded doped | In_{0.53}Ga_{0.47}As | 40 | nm | 1 × 10¹⁸ | P |
| absorption layer | In_{0.53}Ga_{0.47}As | 40 | nm | 2 × 10¹⁸ | P |
| Cap layer | InP | 100 | nm | 2 × 10¹⁸ | P |
| P-contact layer | In_{0.53}Ga_{0.47}As | 50 | nm | 2 × 10¹⁹ | P |
| Buffer layer | InP | 500 | nm | 2 × 10¹⁸ | P |
| Substrate | InP | 350 | μm | | |

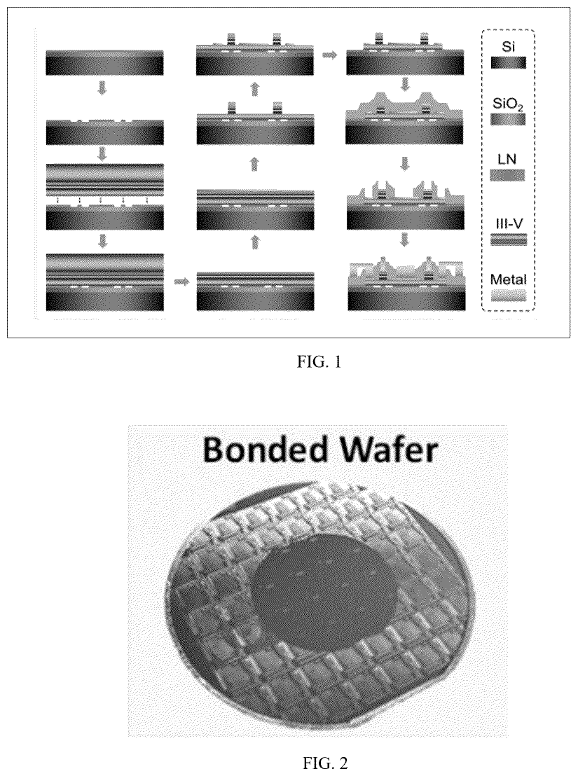

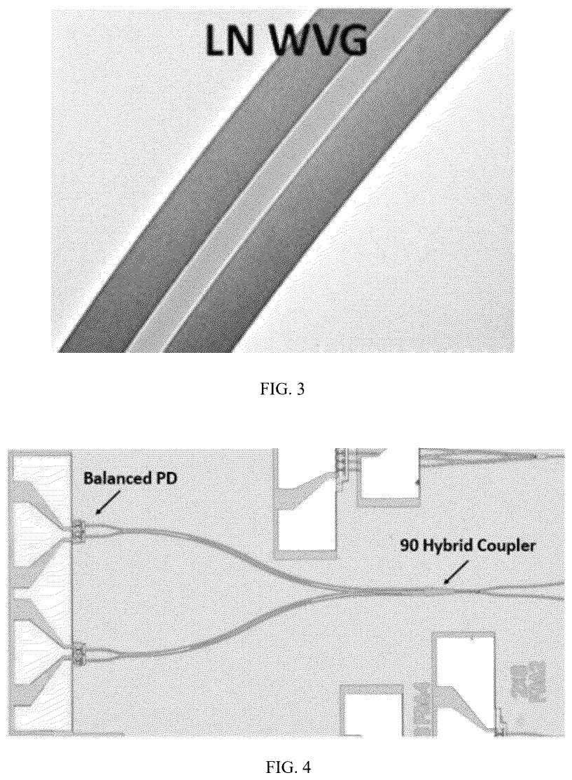

The main fabrication process of the integrated coherent receiver is illustrated in FIG. 1. Before the bonding of an indium phosphide wafer and a thin-film lithium niobate wafer, lithium niobate waveguides and passive devices are fabricated on the thin-film lithium niobate wafer by using an argon-based dry etching process. After the bonding of the indium phosphide wafer and the thin-film lithium niobate wafer, the following steps are sequentially performed: an InP substrate is selectively etched by using a hydrochloric acid-based solution, as illustrated in FIG. 2, a p mesa and an n mesa are fabricated through a chlorine gas dry etching process to form a main structure of the balanced photodetectors, a layer of SiO₂ is deposited over an entire surface as a passivation layer, and metal electrodes are formed by electroplating and lift-off processes after creating openings. FIG. 3 illustrates a colored microscope image of the lithium niobate waveguide.

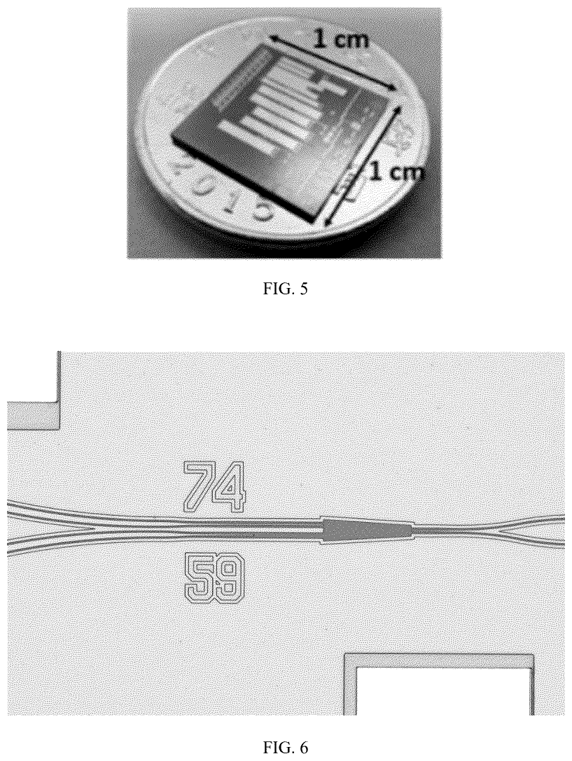

In an embodiment, the heterogeneous integrated coherent receiver based on the wafer-scale InP-lithium niobate integrated platform includes a 2×4 90° optical hybrid coupler (in FIG. 4, 90 Hybrid coupler) and a pair of balanced photodiodes (BPDs) (in FIG. 4, Balanced PD), as shown in FIG. 4. After a wafer is cut into pieces of 1 cm×1 cm, as shown in FIG. 5, coupling loss is minimized by polishing an edge of the wafer. In order to realize a phase relationship required by coherent detection, the 2×4 90° optical hybrid coupler includes a 2×4 multimode interference (MMI) coupler based on symmetrical interference and a 2×2 MMI coupler based on general interference, as shown in FIG. 6.

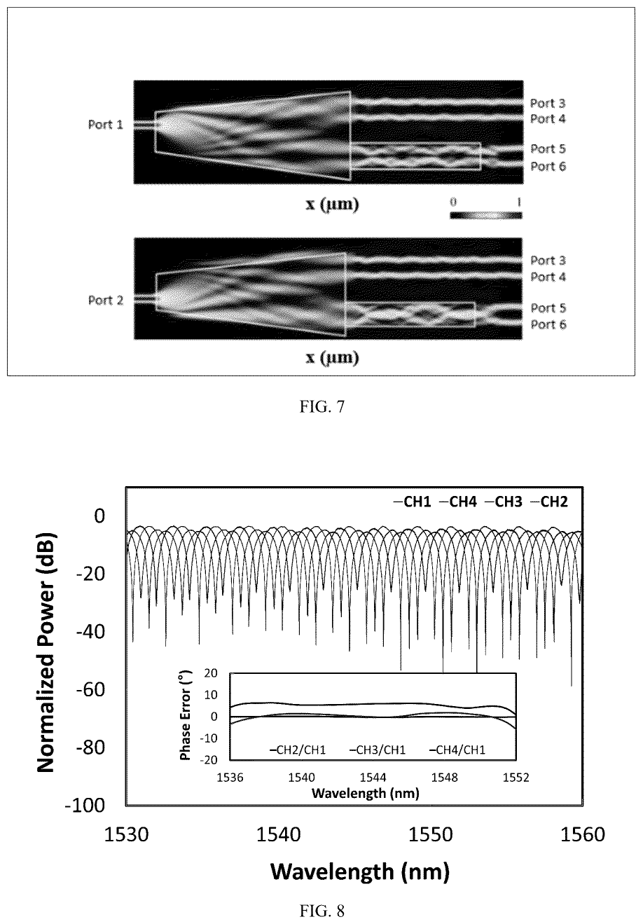

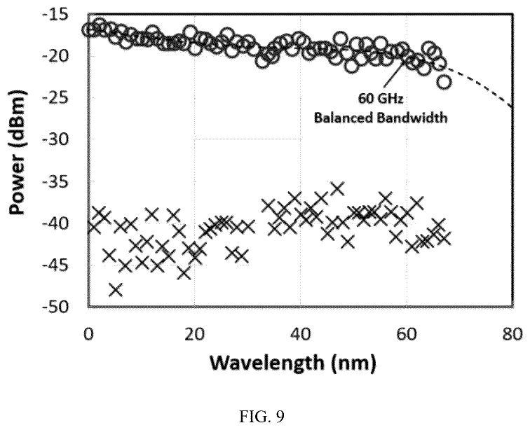

In order to reduce a size of the 2×4 MMI coupler based on symmetrical interference, the 2×4 MMI coupler based on symmetrical interference has a wedge-shaped structure. The 2×2 MMI coupler based on general interference is configured to adjust a phase relationship of one pair of two output pairs of the 2×4 MMI coupler based on symmetrical interference as 90°. Compared with a traditional 4×4 MMI optical hybrid coupler, this design avoids the use of cross waveguides and makes a corresponding device more compact. FIG. 7 illustrates optical simulation of the 2×4 90° optical hybrid coupler using a Lumerical finite difference time domain solver. It can be observed that when light enters the 2×4 90° optical hybrid coupler from any input port, optical power is evenly distributed to each output port. A Mach-Zehnder interferometer (MZI) is used to characterize the performance of the 2×4 90° optical hybrid coupler. The results shown in FIG. 8 show that a phase deviation of the 2×4 90° optical hybrid coupler is less than ±5° in a spectral range of 1536 nm to 1552 nm. In addition, the heterogeneous integrated coherent receiver relies on the performance of the BPDs. Therefore, a bandwidth and a common mode rejection ratio (CMRR) of each BPD are tested by using a heterodyne method. FIG. 9 illustrates frequency responses of the BPD in a differential mode and a common mode. The BPD demonstrates a 3 dB bandwidth of 60 GHz and a common mode rejection ratio greater than 20 dB.

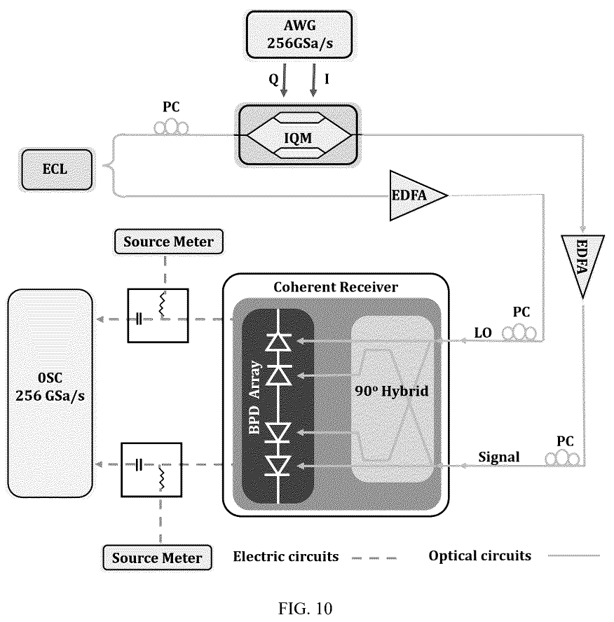

The performance of the heterogeneous integrated coherent receiver (also referred to as a coherent receiving chip) is verified by a coherent receiving system, and an experimental device is shown in FIG. 10. Light emitted by an external cavity laser (ECL) is divided into two paths: one path is modulated by an arbitrary waveform generator (AWG) as signal light; and the other path is used as local oscillation light. The AWG generates different RF signals and amplitude and phase information of modulated light are encoded in I and Q channels. Subsequently, these optical signals are amplified by an erbium-doped fiber amplifier (EDFA) and coupled to the 2×4 90° ptical hybrid coupler through an equal-length fiber with a spot size of 2.5 microns. Four output lights of the 2×4 90° optical hybrid coupler then enter the BPDs (i.e., the balanced photodetector array), and the bias voltage is applied through source meters, bias tees and a customized G-S-G-S-G probe with a frequency range from DC to 67 GHz. The generated RF signal is collected by a real-time oscilloscope and processed by digital signal processing to recover original information.

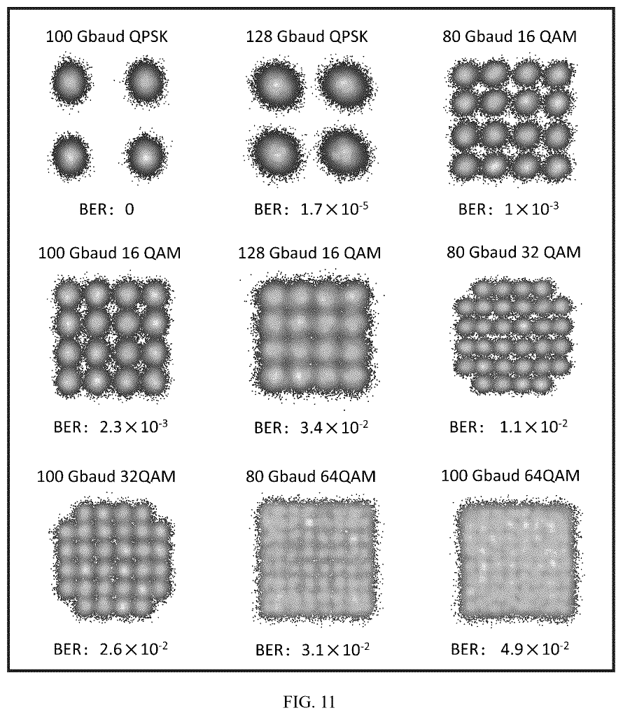

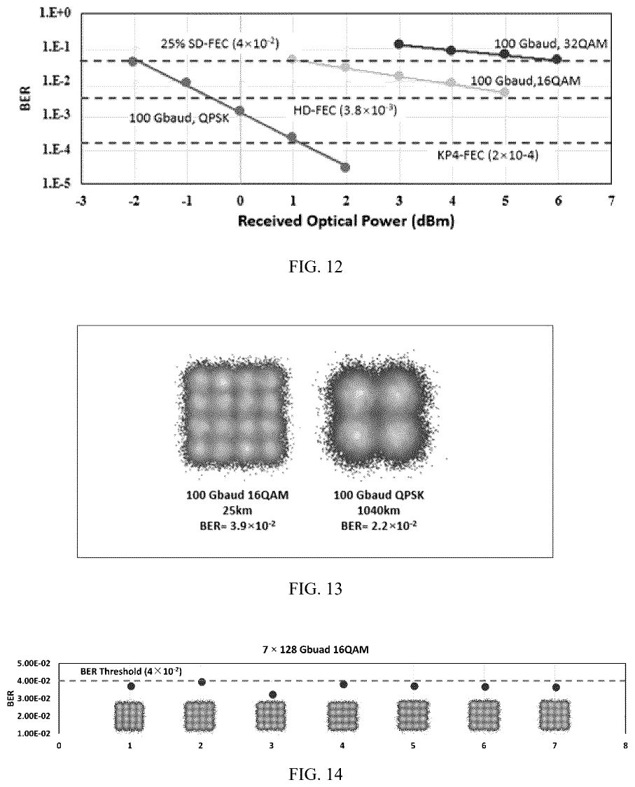

FIG. 11 summarizes constellation diagrams and BER under different signal rates and modulation formats in a back-to-back situation. For QPSK signals, error-free code reception is realized at a rate of 100 Gbaud (200 Gbit/s), and a BER is 1.7×10⁻⁵ for a symbol rate of 128 Gbaud (256 Gbit/s), which is lower than that of key parameter 4 (KP4)-decision forward error correction (FEC). BERs of an 80 Gbaud 16 QAM signal and a 100 Gbaud 16 QAM signal are 1×10⁻³ and 2.3×10⁻³ respectively, which are lower than a hard-decision forward error correction (HD-FEC), and corresponding data rates of the 80 Gbaud 16 QAM signal and the 100 Gbaud 16 QAM signal are 320 Gbit/s and 400 Gbit/s respectively. Under the condition that the BER is lower than a soft-decision forward error correction (SD-FEC), the 128 Gbaud 16 QAM signal (BER=3.4×10⁻²), the 80 Gbaud 32 QAM signal (BER=1.1×10⁻²), the 100 Gbaud 32 QAM signal (BER=2.6×10⁻²) and the 80 Gbaud 64 QAM signal (BER=3.1×10⁻²) can all be successfully received, and a corresponding maximum data rate is 512 Gbit/s. Furthermore, an experimental exploration of the reception of a 100 Gbaud 64 QAM signal, corresponding to a data rate of 600 Gbit/s, yielded a BER of 4.9×10⁻², lower than the 28% SD-FEC limit (5×10⁻²). As shown in FIG. 12, the relationship between back-to-back BER and received optical power is tested for the 100 Gbaud QPSK signal, the 100 Gbaud 16 QAM signal and the 100 Gbaud 32 QAM signal respectively. For the 100 Gbaud QPSK signal, when the received optical power is-2 dBm, 0 dBm and 2 dBm, measured transmission rates are lower than the SD-FEC, the HD-FEC and key parameter (KP)-FEC, respectively. For the 100 Gbaud 16 QAM signal and the 100 Gbaud 32 QAM signal, when incident powers reach 1 dBm and 6 dBm respectively, the received BER is lower than the SD-FEC. In addition, we also carried out long-distance transmission communication experiments with the heterogeneous integrated coherent receiver. Experimental results are shown in FIG. 13. After 25 km single-mode fiber transmission, the BER of the received 100 Gbaud 16 QAM signal is 3.9×10⁻². For the 100 Gbaud QPSK signal, the BER is 2.2×10⁻² after 1040 km transmission. In the experimental device, optical fiber transmission is amplified (a gain of 16 dB) every 80 kilometers (a loss of ~16 dB). Finally, a back-to-back multi-channel communication experiment is carried out on the heterogeneous integrated coherent chip, and results are shown in FIG. 14. When a threshold is 4×10⁻², 7 channels of 128 Gbaud 16 QAM signals are successfully received, which makes the total communication capacity of a monolithic coherent receiver to 3.584. Tbps.

The present disclosure presents for the first time a high-speed thin-film lithium niobate coherent receiver chip, which is the first of its kind realized on the developed InP—LiNbO₃ wafer-scale integration platform. The chip integrates the advantages of InP and LiNbO₃. The heterogeneous integrated coherent receiver features a wide balanced detection bandwidth of 60 GHz and a common mode rejection ratio (CMRR) of more than 20 dB. The single-polarization I/Q coherent receiver combines a compact 2×4 90° optical hybrid coupler and the balanced photodiode (BPD) array, achieving a record receive capacity of 600 Gbit/s/N/Pol for the 100 Gbaud 64 QAM signal. Moreover, it has demonstrated the capability of long-distance reception of the 100 Gbaud QPSK signal over a transmission distance of 1040 kilometers. The work of the present disclosure indicates the potential for Pbit/s-level applications in future ultra-large-scale data center interconnections.

What is claimed is:

1. A heterogeneous integrated coherent receiver based on a wafer-scale indium phosphide (InP)-lithium niobate integrated platform, the heterogeneous integrated coherent receiver comprising: a 2×4 90° optical hybrid coupler and a balanced photodetector array, wherein the 2×4 90° optical hybrid coupler comprises a 2×4 multimode interference (MMI) coupler based on symmetrical interference and a 2×2 MMI coupler based on general interference.

2. The heterogeneous integrated coherent receiver based on the wafer-scale thin-film lithium niobate integrated platform as claimed in claim 1, wherein before bonding of an indium phosphide wafer and a thin-film lithium niobate wafer, lithium niobate waveguides and passive devices are fabricated on the thin-film lithium niobate wafer by using an argon-based dry etching process; and
after the bonding of the indium phosphide wafer and the thin-film lithium niobate wafer, the following steps are sequentially performed: an InP substrate is selectively etched by using a hydrochloric acid-based solution, a p mesa and an n mesa are fabricated through a chlorine gas dry etching process to form a main structure of the balanced photodetector array, a layer of SiO₂ is deposited over an entire surface of the wafer as a passivation layer, and metal electrodes are formed by electroplating and lift-off processes after creating openings.

3. The heterogeneous integrated coherent receiver based on the wafer-scale thin-film lithium niobate integrated platform as claimed in claim 1, wherein the 2×4 MMI coupler based on symmetrical interference has a wedge-shaped structure.

4. The heterogeneous integrated coherent receiver based on the wafer-scale thin-film lithium niobate integrated platform as claimed in claim 1, wherein the 2×2 MMI coupler based on general interference is configured to adjust a phase relationship of one pair of two output pairs of the 2×4 MMI coupler based on symmetrical interference as 90°.

5. The heterogeneous integrated coherent receiver based on the wafer-scale thin-film lithium niobate integrated platform as claimed in claim 1, wherein the heterogeneous integrated coherent receiver has a balanced detection bandwidth of 60 GHz and a power consumption of 9.6 femtojoules (fJ)/bit, and supports data reception of 600 Gbit/s/Pol per channel.
